(19) United States
(12) Patent Application Publication
(10) Pub. No.: US 2023/0266366 A1
(43) Pub. Date: Aug. 24, 2023

(54) METHODS AND SYSTEMS FOR SINUSOIDAL SIGNAL DISTORTION MONITORING AND VISUALIZATION

(71) Applicant: UNIVERSITY OF TENNESSEE RESEARCH FOUNDATION, Knoxville, TN (US)

(72) Inventors: Fangxing Li, Knoxville, TN (US); Haoyuan Sun, Knoxville, TN (US); Christopher Sticht, Key Largo, FL (US); Srijib Mukherjee, Apex, NC (US)

(73) Assignee: UNIVERSITY OF TENNESSEE RESEARCH FOUNDATION, Knoxville, TN (US)

(21) Appl. No.: 18/113,469

(22) Filed: Feb. 23, 2023

Related U.S. Application Data
(60) Provisional application No. 63/268,396, filed on Feb. 23, 2022.

(51) Int. Cl. G01R 13/02; G01R 23/167; G01R 19/00

(52) U.S. Cl. CPC G01R 13/02; G01R 23/167; G01R 19/0053

(57) ABSTRACT

Systems and methods herein provide for sinusoidal signal distortion monitoring and visualization via a Circular Trajectory Approach (CTA). In one embodiment, a system includes a differentiator operable to differentiate an input signal from a sinusoidal signal at substantially a same fundamental frequency of the input signal. The input signal comprising a sinusoidal waveform having distortions. The system also includes a processor operable to calculate a distance index from the input signal to a derivative of the input signal to reveal distortions in the input signal, and a display operable to display the distortions in the input signal.

### CROSS REFERENCE TO RELATED APPLICATIONS

This patent application claims priority to, and thus the benefit of an earlier filing date from, U.S. Provisional Patent Application No. 63/268,396 (filed Feb. 23, 2022), the contents of which are hereby incorporated by reference.

### GOVERNMENT LICENSE RIGHTS

This invention was made with government support under grant numbers R011346289 and R011346234, awarded by the Department of Energy. The government has certain rights in the invention.

### BACKGROUND

Recently, with the integration of renewable energy resources, distributed generation, and power electronic device interfaced facilities, modern power systems are becoming larger, more complex, and have higher uncertainties. High-resolution point-on-wave (POW) data can be recorded for system operation, analysis, and planning. However, present monitoring methods are designed based on phasor measurement unit (PMU) data, which has a rather low sampling rate, typically 60 Hz (e.g., one sample per sinusoidal cycle in a 60 Hz power system).

Additionally, PMU data is filtered and processed to yield synchrophasors. This process eliminates some of the valuable information contained in the original waveforms. Limited by the PMU data, it is difficult for present methods to achieve finer scale monitoring. Contrastingly, POW data has a much higher sample rate and a correspondingly higher resolution. And POW data is recorded with minimal filtering. Therefore, finer scale monitoring of power system signals is facilitated to cover not only large abnormal conditions like amplitude variations, but also small ones like harmonics and other fluctuations (e.g., transients).

In present signal monitoring, numerous trigger conditions are adopted to detect anomalies and to trigger data recording. For example, trigger conditions may include when a pickup value is reached, when a sag or a swell is detected, when a negative or zero sequence component is detected, when a certain frequency component is detected, etc. But some POW devices are triggered for specific faults and do not specifically trigger for or fully record photovoltaic (PV) disconnects, because there is no specific trigger condition for them. And power systems are becoming more complex and uncertain. While more trigger conditions can be added to accommodate such trigger conditions, POW devices still cannot cover all potential circumstances. These trigger conditions also incur a large computational burden. What is needed is a monitoring mechanism that is sensitive to substantially all distortions and/or transients to trigger for data recording and further analysis.

Existing waveform anomaly detection techniques are not suitable for online uses. Edge devices (e.g., computing systems at power substations) have limited computing power and data storage. Existing techniques like those based on fast Fourier transforms (FFTs) usually involve complicated computation, and require a database of abnormal waveforms, mainly because they work on both anomaly detection and classification at the same time. But detection is less complex than classification, and usually more urgent. Thus, it is sensible to separate detection from classification.

Existing detection techniques usually work on waveform segments, or time windows. This means that the detection of any anomaly is delayed by at least the length of these time windows. Further, time windows cause a dilemma between information losses and computational load. For example, small steps and large overlapping captures most information, but greatly increases computation. And large steps and no overlapping minimizes computation, but lead to significant information losses.

Apart from monitoring, another demand when dealing with signals is visualization. One way is to display the signal along the time axis. However, a fluctuating sinusoidal waveform is typically difficult to follow visually. And distortion of a fluctuating waveform is even more difficult to detect because there is no reference.

### SUMMARY

Systems and methods herein provide for sinusoidal signal distortion monitoring and visualization via a Circular Trajectory Approach (CTA). These systems and methods are designed for online sinusoidal signal distortion monitoring and visualization with the following objectives: (1) to achieve finer scale monitoring for sinusoidal signals; (2) to provide a more general solution and replace existing numerous trigger conditions; (3) to induce less computation; (4) to focus on anomaly detection; (5) to achieve earlier detection; (6) to avoid using time windows; and (7) to offer a new means of sinusoidal signal visualization.

In one embodiment, a system includes a differentiator operable to differentiate an input signal (e.g., a power signal of 50 Hz, 60 Hz, etc.) from a sinusoidal signal at substantially a same fundamental frequency of the input signal. The input signal comprises a sinusoidal waveform having distortions (e.g., transients in a power signal). The system also includes a processor operable to calculate a distance index from the input signal to a derivative of the input signal to reveal distortions in the input signal, and a display operable to display the distortions in the input signal.

In some embodiments, the system includes a filter (e.g., an analog or digital low pass filter, and/or an analog or digital band pass filter) operable to filter noise from the input signal. In some embodiments, the distance index corresponds to an amplitude of the input signal. And the processor may be further operable to detect an abnormal transient in the input signal based on the distance index exceeding an upper threshold radius or a lower threshold radius. In some embodiments, the processor is further operable to sample the input signal at a sampling rate of at least 960 Hz.

### BRIEF DESCRIPTION OF THE FIGURES

Some embodiments of the present invention are now described, by way of example only, and with reference to the accompanying drawings. The same reference number represents the same element or the same type of element on all drawings.

FIG. 1 is a block diagram of an exemplary system for monitoring and visualizing sinusoidal signal distortion.

FIG. 2 is a flowchart of an exemplary process of the system of FIG. 1.

FIG. 3 illustrates a sinusoidal signal on the left and its circular trajectory on the right.

FIG. 4 illustrates a workflow of a CTA in one exemplary embodiment.

FIG. 5 illustrates an exemplary voltage signal with harmonics on the left and its circular trajectory on the right.

FIG. 6 illustrates the circular trajectories of the waveform of FIG. 4 with different sampling rates (i.e., 1920 Hz on the left and 960 Hz on the right).

FIG. 7 illustrates an exemplary circular trajectory of a signal with frequency variations in a commonly seen range of ±0.5%, or 60±0.3 Hz.

FIG. 8 illustrates exemplary circular trajectory of a signal with a relatively large frequency variation (e.g., ±5% or 60±3 Hz).

FIG. 9 is a block diagram of an exemplary computing system in which a computer readable medium provides instructions for performing methods herein.

### DETAILED DESCRIPTION OF THE FIGURES

The figures and the following description illustrate specific exemplary embodiments. It will thus be appreciated that those skilled in the art will be able to devise various arrangements that, although not explicitly described or shown herein, embody certain principles and are included within the scope of the embodiments. Furthermore, any examples described herein are intended to aid in understanding the embodiments and are to be construed as being without limitation to such specifically recited examples and conditions. As a result, the embodiments are not limited to any of the examples described below.

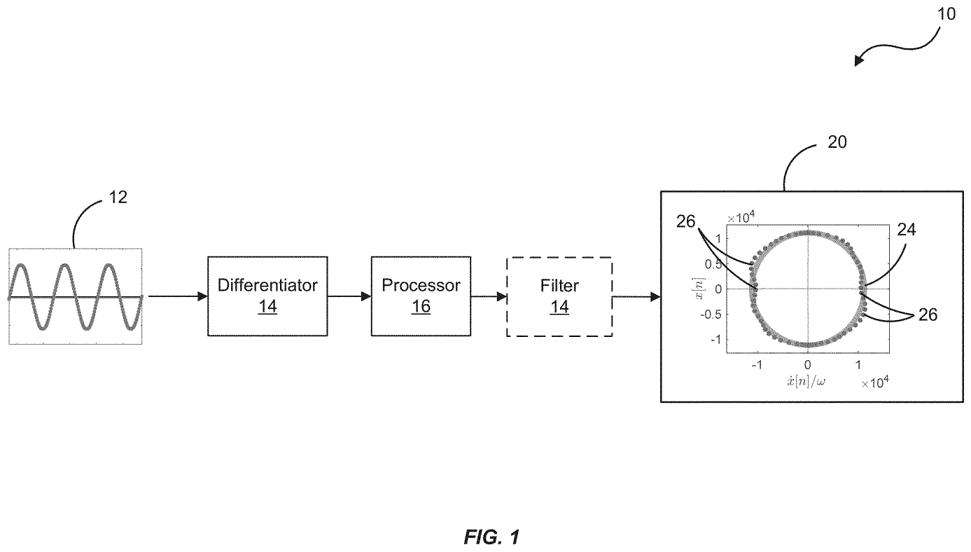

FIG. 1 is a block diagram of a system 10 for monitoring and visualizing distortions in a sinusoidal input signal 12. In this embodiment, the system 10 includes differentiator 14, a processor 16, and a display 20. The differentiator 14 is operable to receive the sinusoidal input signal 12, and to differentiate the input signal from a sinusoidal signal at substantially a same fundamental frequency of the input signal. The input signal 12 is generally a sinusoidal waveform having distortions. For example, the input signal 12 may be a power signal (e.g., 50 Hz, 60 Hz, etc.) that includes various periodic and/or intermittent distortions (e.g., transients, amplitude spikes, etc.). The processor 16 is operable to calculate a distance index from the input signal to a derivative of the input signal to reveal the distortions in the input signal. The distance index generally corresponds to an amplitude of the input signal. And the processor 16 may detect an abnormal transient in the input signal based on the distance index exceeding an upper threshold radius or a lower threshold radius. The display 20 may then display the distortions in the input signal.

In some embodiments, the processor 16 is operable to sample the power signal at at least its fundamental frequency. However, a higher sampling rate may be used to capture more information in the input signal 12. In some embodiments, the sampling rate is at least 960 Hz, but even higher sampling rate such as 1920 Hz or higher may be preferable.

The processor 16 may circularly format the input signal to reveal the distortions in the input signal. From there, the display 20 is operable to display the distortions in the input signal. For example, the processor 16 may compute the circular trajectory of the fundamental frequency of the input signal, as shown in the display 20 with the reference circle 24. The circular trajectory of the input signal 12 is represented by the dots 26. Any transients and/or distortions in the amplitude of the analog input signal cause changes in the radius of the circular trajectory of the input signal 12, resulting in the dots 26 straying inwardly or outwardly from the boundary of the circle 24 (e.g., in real time). Thus, the transients and/or distortions in the input signal 12 can be visualized and more easily monitored, particularly when compared to an amplitude versus time plot of the analog input signal 12.

In some embodiments, a filter 14 may be implemented to filter out noise in the analog input signal 12. Noise is generally inevitable and is introduced at a higher frequency than distortions and transients. The filter 14 may be implemented as an analog filter (e.g., a low-pass filter or a bandpass filter) for filtering the input signal 12. Alternatively or additionally, the filter 14 may be implemented as a digital filter for filtering the input signal 12 after A/D conversion of the input signal.

The differentiator 14 is any device, system, software, or combination thereof operable to differentiate the input signal from a sinusoidal signal at substantially a same fundamental frequency of the input signal. The processor 16 is any device, system, software, or combination thereof operable to calculate a distance index from the input signal to a derivative of the input signal to reveal the distortions in the input signal. For example, the processor may compute the circular trajectory of the input signal 12 such that distortions in the input signal 12 can be monitored and observed in the display 20.

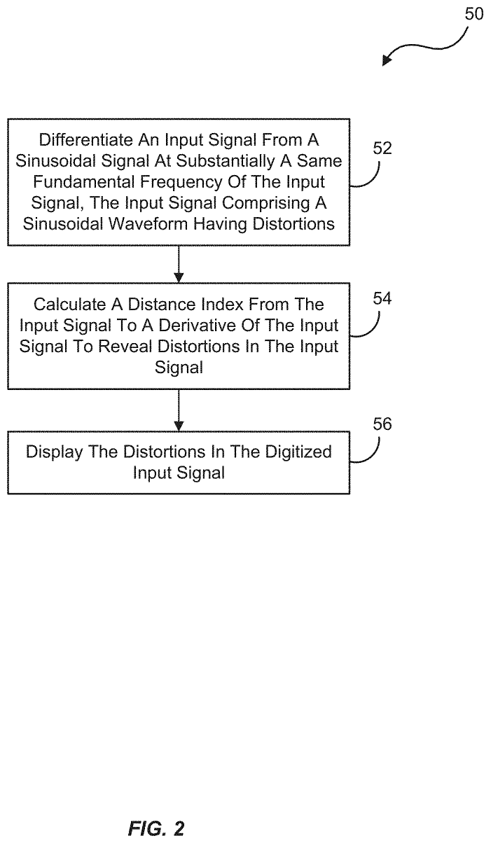

FIG. 2 is a flowchart 50 of an exemplary process of the system 10 of FIG. 1. In this embodiment, the differentiator 14 differentiates the input signal from a sinusoidal signal at substantially a same fundamental frequency of the input signal, in the process element 52. The processor 16 calculates a distance index from the input signal to a derivative of the input signal to reveal the distortions in the input signal, in the process element 54. The input signal is a sinusoidal waveform having distortions. For example, the processor 16 may compute a circular trajectory of the input signal such that it may be displayed on the display 20, in the process element 56, along with any distortions in the input signal.

While these embodiments are particularly useful in monitoring and visualizing distortions and transients in power system signals (e.g., 50 Hz power and 60 Hz power), the embodiments herein may be useful in monitoring and detecting variance in any sinusoidal signal. The embodiments herein are particularly useful in edging computing environments with relatively low processing capabilities, such as power substations and the like.

This circular trajectory approach was generally born from the trigonometric identity:

sin²(ωt)+cos²(ωt)=1, wherein ω is radians per second, and t is time. Eq. 1.

A sinusoidal signal can be transposed to a constant with some calculation, which would be useful for monitoring purposes because a constant is easier to monitor than a sinusoidal signal. And the trajectory of two sinusoidal signals (i.e., if one leads the other by a quarter cycle) is a circle. This “circle” display is then used for monitoring and visualization purposes.

To implement such, two sinusoidal signals are employed. One of these is the signal to be monitored (e.g., the input signal 12). A general sinusoidal signal with amplitude A and initial phase angle φ can be expressed by Eq. 2, with frequency fluctuation taken into consideration and denoted as a function of time ω(t).

x(t)=A sin(∫₀^{t}ω(τ)dτ+φ), where x(t) is the time varying sinusoidal signal. Eq. 2

Since the derivative of a sinusoidal signal is still sinusoidal, one way to obtain the other sinusoidal signal is to take the derivative of the first sinusoidal signal. The derivative of Eq. 2 is as follows:

x(t)=A cos(∫₀^{t}ω(τ)dτ+φ)·ω(t) Eq. 3

Now, by rearranging Eqs. 2 and 3 into a form of Eq. 1, the following equation can be obtained.

x(t)²+(\dot{x}(t)/ω(t))²=A² Eq.4

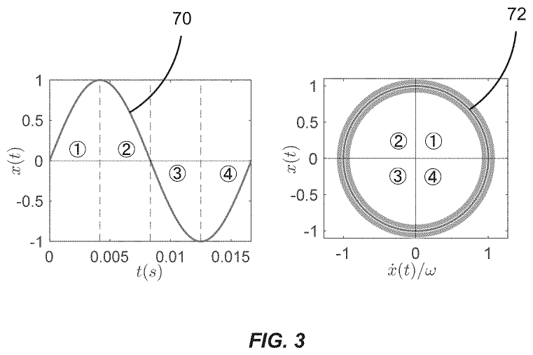

If x(t) is a perfect sine signal (left), then the trajectory of the two sinusoidal terms in Eq. 4 (i.e., x(t) and \dot{x}(t)/ω(t)) is a circle (right) in a 2-D plane, as shown in FIG. 3—i.e., the Circular Trajectory Approach. And the radius of the circular trajectory is the amplitude of the sine signal.

The circular trajectory of any sinusoidal signal x(t), with or without distortions, can be obtained by plotting [\dot{x}(t)/ω(t), x(t)] on a 2-D plane. \dot{x}(t)/ω(t) is deliberately placed along the horizontal axis such that the resulting circular trajectory follows the positive direction of rotation. It can be proven that Eq. 4 should hold if and only if x(t) is a sinusoidal signal.

For example, Eq. 4 holds if and only if x(t) is a sinusoidal signal 70. Thus, it can be derived that:

$$\begin{matrix}dx ( t ) / dt = \pm ω ( t ) \sqrt{{A}^{2} + {x ( t )}^{2}} \\ dx ( t ) / \sqrt{{A}^{2} + {x ( t )}^{2}} = \pm ω ( t ) dt\end{matrix} \vert \begin{matrix}arcsin ( x ( t ) / A ) = \pm \int ω ( t ) dt + {C}_{1} \\ x ( t ) = \pm A sin ( \int ω ( t ) dt + C )\end{matrix}$$

Therefore, x(t) is a sinusoidal signal with amplitude A. This means that the circular trajectory of x(t) is a circle if and only if x(t) is a perfect sinusoidal signal.

CTA can be used for sinusoidal signal anomaly detection. Distortions can be detected by comparing the distance from points on the circular trajectory to the origin with a preset normal value. Deviation from the normal value suggests distortion in the signal. A threshold range [dₘᵢₙ, dₘₐₓ], or “dead band”, can be set around the normal value to accommodate acceptable fluctuations, as shown by in Eq. 5 and the circular ring 72 in FIG. 3. Any point falling out of this range is detected as abnormal. Sensitivity can be tuned by adjusting the range [dₘᵢₙ, dₘₐₓ]. For example,

dₘᵢₙ≤{square root over (x(t)²+(\dot{x}(t)/ω(t))²)}≤dₘₐₓ. Eq. 5

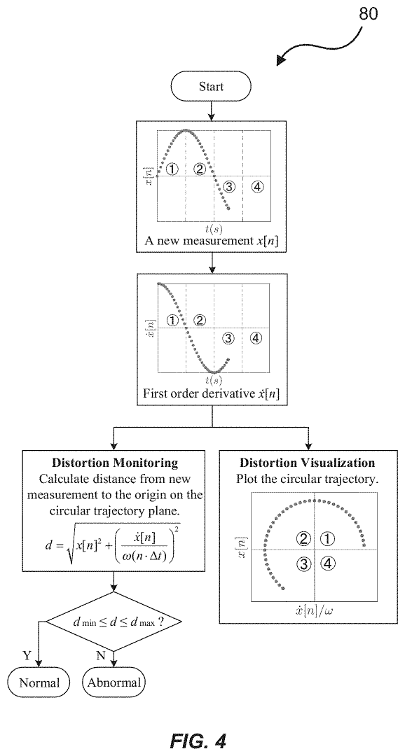

CTA can also be used for sinusoidal signal distortion visualization. For example, a fluctuating signal can be transposed into a steady circular trajectory, from which a distortion is much easier to observe. A full cycle of a sinusoidal signal can be divided into four sections, which correspond to the four quadrants of the circular trajectory plane, as shown in FIG. 3. The same section of each cycle corresponds to the same quadrant. This property helps reveal which section of the sinusoidal signal is distorted. A workflow 80 of the CTA is presented in FIG. 4.

For the ω(t) part in Eq. 5, instantaneous frequency measurements may be used. Frequency measurements with a 1440 Hz reporting rate are already available in edge computing at power substations, which is high enough for distortion monitoring purposes.

Using the nominal frequency as an approximation of ω(t) is also practical, as CTA no longer needs frequency measurements, leading to a more elegant solution. However, this may come at a price of potential systematic error. Commonly observed frequency fluctuation is generally within ±0.5%, or ±0.3 Hz for a nominal frequency of 60 Hz. The largest error for left hand side of Eq. 4 occurs when \dot{x}(t) reaches its maximum Aω(t) and ω(t) reaches its minimum ωₘᵢₙ=59.7 Hz, as given by Eq. 6.

εₘₐₓ=|(Aωₘᵢₙ/ωₘᵢₙ)²−(Aωₘᵢₙ/ωₙ)²|/A²=1% Eq. 6

Practically speaking, the sinusoidal signal to be monitored is available as a sequence of discrete measurements. A discrete sinusoidal signal and its derivative can be described as follows:

x[n]A sin(∫₀^{n·Δt}ω(τ)dτ+φ), and Eq. 7

\dot{x}[n]A cos(∫₀^{n·Δt}ω(τ)dτ+φ)·ω(n·Δt), Eq. 8

where Δt is the sampling period, n·Δt is the timestamp of the measurement x[n], and x[0] is assumed to be measured at t=0. Eq. 4 can then be written in discrete form as follows:

x[n]²+(\dot{x}[n]/ω(n·Δt))²=A² Eq. 9

Numerical differentiation can be used to obtain the derivative of such sequence of measurements as Eq. 7. To determine the numerical differentiation formula to be used, an error and computing time comparison may be conducted using a segment of a perfect sine wave. The result of which is shown in Table I.

TABLE I
Error and Computing Time Comparison
of Numerical Differentiation Formulas

| | | | Avg. compute |
|---|---|---|---|
| | Max relative err. | Avg. relative err. | time |
| 2-point formula | 4.9% | 3.1% | 0.87 μs |
| 3-point formula | 0.32% | 0.16% | 0.88 μs |
| 5-point formula | 0.0006% | 0.0003% | 1.70 μs |

High order methods achieve better accuracy, but can also induce more computation. The 3-point formula, as given by Eq. 10, is adopted here as a trade-off between accuracy and complexity.

\dot{x}[n]=(x[n+1]−x[n−1])/2Δt Eq. 10

Derivative sensors can be developed and deployed, such that the above numerical differentiation process can be saved, and CTA will thus become faster and incur even less computation.

Real data inherently contains noise, and two techniques herein are designed to deal overcome those effects. Because noise is smaller than the distortions of interest, a proper threshold range or dead band [dₘᵢₙ, dₘₐₓ] for detection and monitoring purposes can be set to filter out the noise, such that the CTA only reacts to distortions. Because noise is random and distortions usually have repeating patterns, it helps to superimpose the circular trajectories of a few consecutive cycles for visualization purposes, such that the repeating patterns of distortion stand out while random noise becomes much less noticeable.

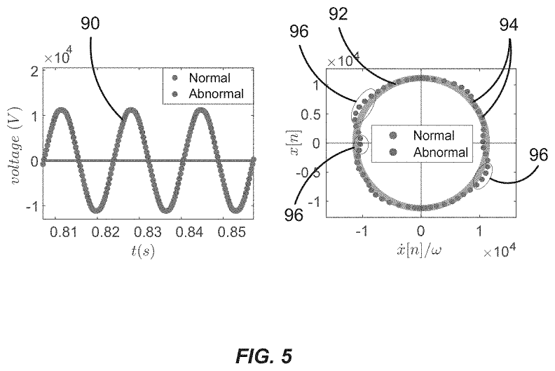

The proposed CTA was tested on real event recordings from an open source Electric Power Research Institute (EPRI) dataset. FIG. 5 shows a voltage signal 90 and its circular trajectory 94. The dead band [dₘᵢₙ, dₘₐₓ] is set to 11,180 V±5% in this embodiment. Any point falling out of this range is detected as abnormal, denoted by regions 96. Looking at only the waveform, it is very difficult to tell whether this sine wave is distorted and at what time the distortion occurs. However, the circular trajectory reveals that the signal is indeed distorted, and the distorted sections are clearly reflected. Results from Fourier analysis confirm the existence of harmonics, as shown in Table II below.

TABLE II
Frequency Components of the Voltage Signal in FIG. 5.

| Frequency Component | Amplitude | Relative Value |
|---|---|---|
| 60 Hz/1st order | 11,188.42 | 100% |
| 180 Hz/3rd order | 115.66 | 1.03% |
| 300 Hz/5th order | 186.71 | 1.67% |
| 420 Hz/7th order | 37.47 | 0.33% |
| 540 Hz/9th order | 67.08 | 0.60% |

To assess the computational load of the CTA, a runtime comparison was conducted. The FFT algorithm was chosen as the benchmark because it is efficient and widely used in signal processing. Theoretically, FFT has a computational complexity of O(N log₂N), while the CTA embodiments have a computational complexity of O(N). The waveform segment presented in FIG. 5 was used for this experiment. The length of the segment was 194. Both algorithms were executed 1 million times to reduce relative error in runtime measurement. The FFT took 9.47 seconds, while the CTA took 1.41 μs. This verifies that the CTA requires much less computation, making it more suitable for edge computing than existing techniques.

A sufficiently high sample rate is important for achieving a satisfying accuracy with numerical differentiation, and also important for revealing more details of a piece of waveform with the CTA. An error comparison of the three-point formula under different sample rates is presented in Table III below.

TABLE III
Error Comparison of 3-Point Formula
under Different Sample Rates

| Sample Rate | Max Relative Error | Average Relative Error |
|---|---|---|
| 6000 Hz | 0.13% | 0.07% |
| 3840 Hz* | 0.32% | 0.16% |
| 1920 Hz | 1.28% | 0.64% |
| 960 Hz | 5.04% | 2.52% |

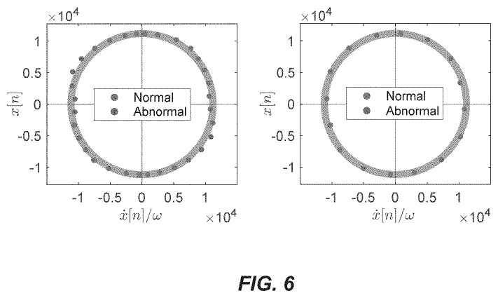

The circular trajectories of the same waveform segment in FIG. 5, but with lower sample rates, are shown in FIG. 6. With lower sample rates, the trajectories become much less informative. Future grid sensors, however, will have a sample rate of 6000 Hz or higher, which is sufficient for satisfactory performance of the CTA.

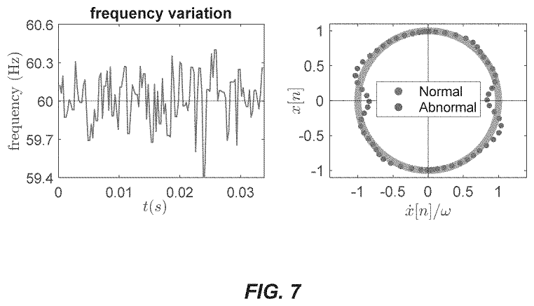

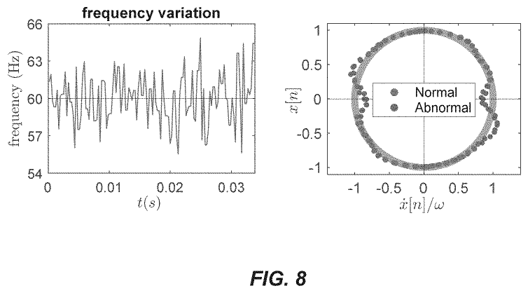

Power systems undergo constant frequency variations. To determine how this affects the CTA, test signals with frequency variations were generated based on the frequency components given in Table II to mimic the voltage signal 90 in FIG. 5. By comparing FIGS. 6, 7, and 8, it can be concluded that the CTA can still detect sinusoidal waveform distortions when the input signal contains frequency variations.

The CTA's sinusoidal signal distortion monitoring and visualization achieves finer scale and more generic sinusoidal signal monitoring, and can detect distortions of a sinusoidal signal. And the dead band can be set to adjust the sensitivity. As such, the CTA offers a new means of sinusoidal signal distortion visualization, which can reveal the distorted sections in a sinusoidal cycle, and clearly display distortions, even relatively small ones. In some embodiments, the CTA may determine how the shape of the circular trajectory is related to the order, amplitude, and phase angle of the harmonic components to assist in anomaly classification.

While the embodiments disclosed herein are helpful in providing visualization of distortions in power signals, the embodiments herein may be used to provide such in a variety of sinusoidal signals, particularly where such signals are analyzed in environments with signal processing constraints.

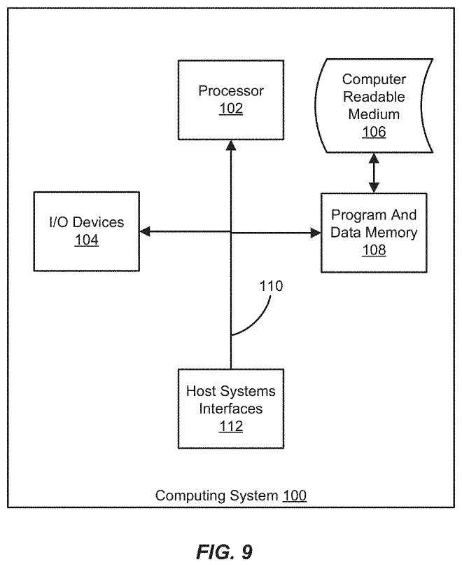

Any of the above embodiments herein may be rearranged and/or combined with other embodiments. Accordingly, the concepts herein are not to be limited to any particular embodiment disclosed herein. Additionally, the embodiments can take the form of entirely hardware or comprising both hardware and software elements. Portions of the embodiments may be implemented in software, which includes but is not limited to firmware, resident software, microcode, etc. FIG. 9 illustrates a computing system 100 in which a computer readable medium 106 may provide instructions for performing any of the methods disclosed herein.

Furthermore, the embodiments can take the form of a computer program product accessible from the computer readable medium 106 providing program code for use by or in connection with a computer or any instruction execution system. For the purposes of this description, the computer readable medium 106 can be any apparatus that can tangibly store the program for use by or in connection with the instruction execution system, apparatus, or device, including the computer system 100.

The medium 106 can be any tangible electronic, magnetic, optical, electromagnetic, infrared, or semiconductor system (or apparatus or device). Examples of a computer readable medium 106 include a semiconductor or solid state memory, magnetic tape, a removable computer diskette, a random access memory (RAM), NAND flash memory, a read-only memory (ROM), a rigid magnetic disk and an optical disk. Some examples of optical disks include compact disk—read only memory (CD-ROM), compact disk—read/write (CD-R/W) and digital versatile disc (DVD).

The computing system 100, suitable for storing and/or executing program code, can include one or more processors 102 coupled directly or indirectly to memory 108 through a system bus 110. The memory 108 can include local memory employed during actual execution of the program code, bulk storage, and cache memories which provide temporary storage of at least some program code in order to reduce the number of times code is retrieved from bulk storage during execution. Input/output or I/O devices 104 (including but not limited to keyboards, displays, pointing devices, etc.) can be coupled to the system either directly or through intervening I/0 controllers. Network adapters may also be coupled to the system to enable the computing system 100 to become coupled to other data processing systems, such as through host systems interfaces 112, or remote printers or storage devices through intervening private or public networks. Modems, cable modem and Ethernet cards are just a few of the currently available types of network adapters.

What is claimed is:

1. A system, comprising:
a differentiator operable to differentiate an input signal from a sinusoidal signal at substantially a same fundamental frequency of the input signal, the input signal comprising a sinusoidal waveform having distortions;
a processor operable to calculate a distance index from the input signal to a derivative of the input signal to reveal distortions in the input signal; and
a display operable to display the distortions in the input signal.

2. The system of claim 1, further comprising:
a filter operable to filter noise from the input signal.

3. The system of claim 1, wherein:
the input signal is a power signal; and
the distortions comprise transients in the power signal.

4. The system of claim 1, wherein:
the distance index corresponds to an amplitude of the input signal.

5. The system of claim 4, wherein:
the processor is further operable to detect an abnormal transient in the input signal based on the distance index exceeding an upper threshold radius or a lower threshold radius.

6. The system of claim 1, wherein:
the processor is further operable to sample the input signal at a sampling rate of at least 960 Hz.

7. A method, comprising:
differentiating an input signal from a sinusoidal signal at substantially a same fundamental frequency of the input signal, the input signal comprising a sinusoidal waveform having distortions;
calculating a distance index from the input signal to a derivative of the input signal to reveal distortions in the input signal; and
displaying the distortions in the input signal.

8. The method of claim 7, further comprising:
filtering noise from the input signal.

9. The method of claim 7, wherein:
the input signal is a power signal; and
the distortions comprise transients in the power signal.

10. The method of claim 7, wherein:
the distance index corresponds to an amplitude of the input signal.

11. The method of claim 10, further comprising:
detecting an abnormal transient in the input signal based on the distance index exceeding an upper threshold radius or a lower threshold radius.

12. The method of claim 7, further comprising:
sampling the input signal at a sampling rate of at least 960 Hz.

13. A non-transitory computer readable medium comprising instructions that, when executed by one or more processors, directs the one or more processors to:
differentiate an input signal from a sinusoidal signal at substantially a same fundamental frequency of the input signal, the input signal comprising a sinusoidal waveform having distortions;
calculate a distance index from the input signal to a derivative of the input signal to reveal distortions in the input signal; and
display the distortions in the input signal.

14. The computer readable medium of claim 13, further comprising instructions that direct the one or more processors to:
filter noise from the input signal.

15. The computer readable medium of claim 13, wherein:
the input signal is a power signal; and
the distortions comprise transients in the power signal.

16. The computer readable medium of claim 13, wherein:
the distance index corresponds to an amplitude of the input signal.

17. The computer readable medium of claim 16, further comprising instructions that direct the one or more processors to:
detect an abnormal transient in the input signal based on the distance index exceeding an upper threshold radius or a lower threshold radius.

18. The computer readable medium of claim 13, further comprising instructions that direct the one or more processors to:
sample the input signal at a sampling rate of at least 960 Hz.
